(19) United States
(12) Patent Application Publication
(10) Pub. No.: US 2025/0366373 A1
(43) Pub. Date: Nov. 27, 2025

(54) PIEZOELECTRIC ELEMENT AND MANUFACTURING METHOD THEREOF

(71) Applicant: CHUNG-YUAN CHRISTIAN UNIVERSITY, Tao Yuan County (TW)

(72) Inventors: Yung TING, Tao Yuan County (TW); Sheuan-Perng LIN, Tao Yuan County (TW); Masroor Ahmad SOFI, Baramulla (IN); Hao-Chun YANG, Tao Yuan County (TW); Ping-Che LU, Tao Yuan County (TW)

(21) Appl. No.: 18/952,617

(22) Filed: Nov. 19, 2024

(30) Foreign Application Priority Data
May 27, 2024 (TW) 113119567

(51) Int. Cl. H10N 30/85; H10N 30/092

(52) U.S. Cl. CPC H10N 30/852; H10N 30/092

(57) ABSTRACT

A piezoelectric element and its manufacturing method are disclosed, wherein the piezoelectric element includes a piezoelectric composite material and at least one polarization zone, characterized in that the piezoelectric composite material is composed of piezoelectric ceramic powder and thermoplastic elastomer, wherein a piezoelectric hybrid blank is formed through a mixing process of the piezoelectric ceramic powder with the thermoplastic elastomer and the piezoelectric hybrid blank is formed into a piezoelectric composite material after injection and thermoplastic processes. The piezoelectric composite material is thickness polarized or surface polarized to produce the piezoelectric element. There is at least one polarization zone, in which the volume ratio of piezoelectric ceramic powder is between 40% and 80%.

### BACKGROUND

### 1. Technical Field

The present invention relates to a piezoelectric element and its manufacturing method, specifically focusing on a piezoelectric element where the piezoelectric element of the piezoelectric composite material is selected from thermoplastic elastomers (TPEs) that can be physically and uniformly mixed with ceramic powder. In particular, thermoplastic polyurethane (TPU) is chosen, and even when a substantial proportion (e.g., above 40%) of piezoelectric ceramic powder is added, the piezoelectric element of this invention retains good elasticity.

### 2. Description of the Related Art

Generally, the flexibility of piezoelectric materials is improved by reducing the thickness or combining such materials with substrate materials. In 0-3 type composite materials, traditional manufacturing methods often require expensive polymer fine powders, ceramic powders, and molding agents for dry mixing to achieve uniform mixing of ceramic powder with the substrate material. This is followed by kneading and extrusion molding using an extruder to form a green compact sheet. Afterward, high-temperature hot pressing is used for densification and combination with the composite structure. Alternatively, a base liquid adhesive can be mixed with ceramic powder along with a curing agent and then left to stand in a mold or heated for a curing process to occur. Another method involves dissolving the base material in a large amount of chemical solutions and then adding ceramic powder and stirring to form a slurry. This slurry can be cast into molds or spread into a wet green tape using a scraper before being heated and baked to evaporate the solvent and form a dry thin tape, followed by high-temperature hot pressing for densification and shaping. All of the above processes encounter issues such as ceramic powder agglomeration, uneven distribution during dry mixing, and difficulty in achieving uniform mixing due to the high viscosity of the slurry or adhesive. During the curing or solvent removal process, the significant density difference between the ceramic and polymer can easily generate density gradients, layering, and bubble formation. Additionally, high-temperature hot pressing for densification tends to generate cracks. Another concern is that the addition of solvents, molding agents, curing agents, and other chemical solutions in the manufacturing process is not environmentally friendly. The manufacturing steps are complex, and the resulting components are typically thin, making them difficult to handle and apply. There is a need for improvements in producing high-quality, highly flexible, large-sized thick materials and various 3D-shaped components for practical applications.

### SUMMARY

The main objective of this invention is to provide a piezoelectric element with excellent piezoelectric properties and high elasticity. Even with a piezoelectric ceramic powder content exceeding 40%, the ceramic powder remains uniformly distributed. The piezoelectric element of this invention successfully maintains high elasticity.

Another main objective of this invention is to provide a piezoelectric composite material for manufacturing the aforementioned piezoelectric element. The composite material is selected from thermoplastic elastomers (TPEs), which can be directly blended with piezoelectric ceramic powder during the mixing stage without the need for chemical solvents or surfactants.

The piezoelectric composite material of the present disclosure is specifically selected thermoplastic polyurethane (TPU). Even when a high proportion (over 40%) of piezoelectric ceramic powder is added, the piezoelectric element can still maintain good elasticity.

To achieve the above-mentioned objects, the piezoelectric element of the present disclosure includes a piezoelectric composite material and at least one polarization zone. The present disclosure is characterized in that the piezoelectric composite material is composed of a piezoelectric ceramic powder and a thermoplastic elastomer (TPE), wherein the piezoelectric ceramic powder and the thermoplastic elastomer form a piezoelectric mixed blank through a mixing procedure, the piezoelectric mixed blank becomes the piezoelectric composite material after injection and thermoplastic procedures, and thickness poling or surface poling is performed on the piezoelectric composite material to generate at least one polarization zone, wherein a weight ratio of the piezoelectric ceramic powder to the thermoplastic elastomer ranges from 0.3:1 to 3:1.

The present disclosure further provides a wearable item including the above-mentioned piezoelectric element, wherein the wearable item includes multiple polarization zones.

The present disclosure further provides piezoelectric element manufacturing method for manufacturing a piezoelectric element. The piezoelectric element includes a piezoelectric composite material and at least one polarization zone, and the piezoelectric element manufacturing method includes the following steps: mixing the piezoelectric ceramic powder and the thermoplastic elastomer (TPE) in a hot melt liquefied state to form a piezoelectric mixed blank during a mixing procedure, wherein a volume ratio of the piezoelectric ceramic powder ranges from 40% to 80%; the piezoelectric mixed blank becoming the piezoelectric composite material after injection and thermoplastic procedures; and, performing thickness poling or surface poling on the piezoelectric composite material to generate at least one polarization zone such that the piezoelectric element is formed.

The manufacturing process of the present disclosure involves directly mixing ceramic powder with thermoplastic elastomers (such as TPE, foamed cotton, TPU, or TPU foamed cotton) without the addition of chemical solvents. The mixture is then subjected to high-pressure heat injection molding or hot pressing to produce piezoelectric composite materials that are high in density, high in strength, and highly flexible, with varying thicknesses. These materials are suitable for use in large flat panels and 3D components.

The present disclosure also includes the combined use of injection molding and hot pressing (e.g., multiple hot pressing cycles following injection molding) to produce high-performance piezoelectric composite materials. For example, a piezoelectric mixed blank produced by injection molding can be cut to match the desired mold geometry and then placed into a hot press mold. In a hot press machine, the piezoelectric mixed blank is heated and pressed until the thermoplastic elastomer within the blank softens. After cooling and demolding, a 3D piezoelectric composite material is obtained. This method, along with precise molding tools and hot pressing techniques, enables the production of 3D piezoelectric composite materials with exact dimensions and thicknesses and allows for direct polarization of the formed piezoelectric composites. The formed piezoelectric composite material, after electrode printing and high-voltage polarization, can be developed into a smart material with two functional components: a sensor that generates a voltage signal in response to deformation (the piezoelectric direct effect) and an actuator that produces deformation when a voltage is applied (the piezoelectric converse effect). Additionally, thickness poling or surface poling can be performed in areas where data collection is needed to enhance the smart material's functionality and make it highly advantageous for the production of multi-point sensors or actuators.

The piezoelectric element of the present disclosure can be fabricated into various forms, such as rings, cylindrical tubes, and complex shapes like gloves. It enables the creation of multi-point sensors or actuators at specific locations as needed. Additionally, the piezoelectric element can be pre-attached to a substrate made from a different material (i.e., a material with properties distinct from those of the piezoelectric element) before being cut and thermally pressed into shape. For applications such as haptic gloves and smart clothing, the piezoelectric element can first be bonded to the base material of the haptic glove or smart clothing, followed by processes such as thermal pressing and polarization. This approach enhances the manufacturing process for haptic gloves and smart clothing.

### BRIEF DESCRIPTION OF THE DRAWINGS

The accompanying drawings described here are provided to facilitate a further understanding of the present application and constitute a part of this application. The illustrative embodiments and their descriptions are used to explain the present application and do not constitute undue limitations on it. In the drawings:

FIG. 1 is a flowchart illustrating the steps of the piezoelectric element manufacturing method according to one embodiment of the present disclosure.

FIG. 2 is a scanning electron microscope (SEM) image of the piezoelectric composite material in one embodiment of the present disclosure manufactured with 50% by volume of the piezoelectric ceramic powder and 50% by volume of the thermoplastic polyurethane (TPU).

FIG. 3 is a scanning electron microscope (SEM) image of the piezoelectric composite material in one embodiment of the present disclosure manufactured with 60% by volume of the piezoelectric ceramic powder and 40% by volume of the thermoplastic polyurethane (TPU).

FIG. 4 is a schematic diagram of the piezoelectric composite material of the present disclosure after thickness poling has been performed thereon.

FIG. 5 is a schematic diagram of the piezoelectric composite material of the present disclosure after surface poling has been performed thereon.

FIG. 6 is a schematic diagram of a ring-shaped embodiment of the piezoelectric composite material of the present disclosure after thickness poling has been performed thereon.

FIG. 7 is a schematic diagram of a cylindrical tubes shape embodiment of the piezoelectric composite material of the present disclosure after planar poling has been performed thereon.

FIG. 8 is a schematic diagram of an embodiment of the piezoelectric element of the present disclosure used in haptic gloves.

FIG. 9 is a schematic diagram of an embodiment of the piezoelectric element of the present disclosure used in smart clothing.

### DETAILED DESCRIPTION OF THE EMBODIMENTS

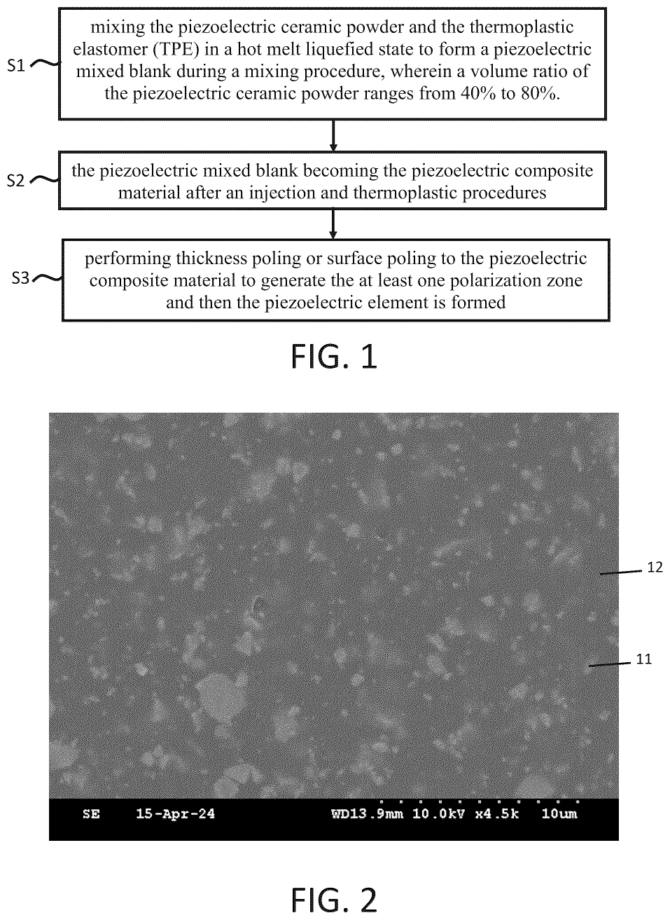

The following drawings disclose multiple embodiments of the present application. For the sake of clarity, many implementation details will be described in the following narration. Please refer to FIG. 1 to FIG. 5, which are related to the steps of the piezoelectric element manufacturing method according to one embodiment of the present disclosure, scanning electron microscope (SEM) images of the piezoelectric composite material in one embodiment of the present disclosure manufactured with 50% and 60% by volume of the piezoelectric ceramic powder, a schematic diagram of the piezoelectric composite material of the present disclosure after thickness poling has been performed thereon, and a schematic diagram of the piezoelectric composite material of the present disclosure after surface poling has been performed thereon.

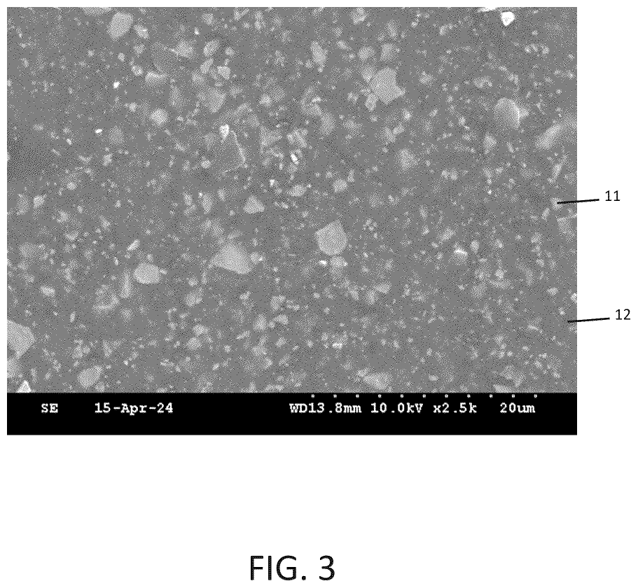

FIG. 1, FIG. 2, and FIG. 3 present, in this embodiment, the piezoelectric element manufacturing method of the present disclosure for manufacturing a piezoelectric element 1. The piezoelectric element 1 includes a piezoelectric composite material 10 and at least one polarization zone 20, wherein the piezoelectric composite material 10 is composed of a piezoelectric ceramic powder 11 and a thermoplastic elastomer 12. The piezoelectric element manufacturing method of the present disclosure includes the following steps:

Step S1: mixing the piezoelectric ceramic powder and the thermoplastic elastomer (TPE) in a hot melt liquefied state to form a piezoelectric mixed blank during a mixing procedure, wherein a volume ratio of the piezoelectric ceramic powder ranges from 40% to 80%.

In the present disclosure, a ceramic kneader is used to physically blend the piezoelectric ceramic powder 11 with the thermoplastic elastomer 12 (TPE) in a molten state through repeated twin-screw kneading and mixing to form a piezoelectric mixed blank. In other words, during the mixing process of the piezoelectric ceramic powder 11 with the thermoplastic elastomer 12 in a molten state, no chemical solutions (such as DMF) or surface active agents are added. The piezoelectric ceramic powder of the present disclosure can be either a soft piezoelectric ceramic powder (such as PZT5A or PZT5H) or a hard piezoelectric ceramic powder (such as PZT4 or PZT8), However, the present disclosure is not limited to these types, as other forms of piezoelectric ceramics are also applicable in the present disclosure. When the piezoelectric ceramic powder has a particle size of 1 μm to 20 μm, 5 μm to 15 μm, or 10 μm to 20 μm, the physical mixing of the piezoelectric ceramic powder 11 with the thermoplastic elastomer 12 in a molten state yields good results, with excellent polarization effects (as compared with previous techniques that involved adding chemical solvents or surfactants). The piezoelectric output characteristics of the piezoelectric element of the present disclosure are proportional to the content of the piezoelectric ceramic powder, while its flexibility (softness) is proportional to the content of the thermoplastic elastomer. Experiments have shown that when the weight ratio of the piezoelectric ceramic powder to the thermoplastic elastomer is between 0.3:1 and 3:1, the piezoelectric composite material 10 allows the piezoelectric element 1 of the present disclosure to achieve both high piezoelectricity and good flexibility Alternatively, when the volume percentage of the piezoelectric ceramic powder is between 45% and 85%, between 40% and 80%, or between 45% and 75%, the piezoelectric composite material 10 similarly allows the piezoelectric element 1 to achieve both high piezoelectricity and good flexibility. Correspondingly, the volume percentage of the thermoplastic elastomer 12 is between 15% and 55%, between 20% and 60%, or between 25% and 55%.

According to one embodiment of the present disclosure, the thermoplastic elastomer 12 can be foamed cotton (e.g., foamed cotton used for cushioning at construction sites, in buildings, or in shoe insoles). Leveraging the material properties of foamed cotton allows the piezoelectric ceramic powder 11, with a volume ratio greater than 40%, to be more evenly blended with the foamed cotton (thermoplastic elastomer 12) during the kneading process. It should be noted that to maintain the high elasticity of the thermoplastic elastomer 12, it is recommended that the foamed cotton not undergo the foaming process yet still be evenly mixed. For example, preventing the foaming process could involve limiting the heating of the foamed cotton to temperatures below 180° C. or 140° C. and/or not introducing air or compounds into the foamed cotton.

According to another embodiment of the present disclosure, the thermoplastic elastomer 12 is thermoplastic polyurethane (TPU). The TPU used in this embodiment can be a plasticizer-free elastomer or the commonly used TPU foamed cotton found in shoe outsoles (for absorbing walking shocks). By leveraging the material properties of foamed cotton, the piezoelectric ceramic powder 11, with a volume ratio greater than 40%, can be evenly blended with the molten foamed cotton (thermoplastic elastomer 12) during the kneading process, without the addition of compounds or air that could cause thermoplastic elastomer 12 to foam. In this embodiment of the present disclosure, the softening point of the thermoplastic polyurethane (TPU) product ranges from 50° C. to 105° C., the initial flow temperature ranges from 50° C. to 145° C., and the hardness ranges from 60A and 95A.

FIG. 2 is a scanning electron microscope (SEM) image of the piezoelectric composite material in one embodiment of the present disclosure manufactured with 50% by volume of the piezoelectric ceramic powder and 50% by volume of the thermoplastic polyurethane (TPU); FIG. 3 is a scanning electron microscope (SEM) image of the piezoelectric composite material in one embodiment of the present disclosure manufactured with 60% by volume of the piezoelectric ceramic powder and 40% by volume of the thermoplastic polyurethane (TPU). It is shown in FIG. 2 and FIG. 3, whether the volume ratio of the piezoelectric ceramic powder is 50% or 60%, the piezoelectric ceramic powder of the piezoelectric composite material of the present disclosure is generally uniformly distributed, with no significant agglomeration, layering, or the presence of bubbles.

According to one embodiment of the present disclosure, when the piezoelectric element 1 functions as an actuator, the piezoelectric ceramic powder 11 of the piezoelectric composite material 10 used for the previously mentioned piezoelectric element 1 has a volume ratio of 60% to 80% (i.e., high piezoelectric ceramic content), achieving a composite characteristic of both strong piezoelectricity and flexibility. When the piezoelectric element 1 functions as a sensor, the piezoelectric ceramic powder 11 of the piezoelectric composite material 10 used for the previously mentioned piezoelectric element 1 has a volume ratio of 40% to 60% (i.e., low piezoelectric ceramic content), also achieving a composite characteristic of both piezoelectricity and flexibility.

It is noted that the piezoelectric mixed blank of the present disclosure is formed by kneading the piezoelectric ceramic powder 11 with thermoplastic elastomer 12 in the molten state without adding any chemical solutions or surface active agents. Although the absence of chemical solutions or surface active agent results in weaker molecular bonding of the piezoelectric ceramic powder 11 to the molten thermoplastic elastomer 12 (such as PE, foamed cotton, TPU, or TPU foamed cotton) in the piezoelectric mixed blank as compared with previous techniques that use chemical solvents, this weakened molecular bonding can enhance the polarization effect (Step S3) of the piezoelectric element 1 in the present disclosure.

Step S2: the piezoelectric mixed blank becoming the piezoelectric composite material after injection and thermoplastic procedures.

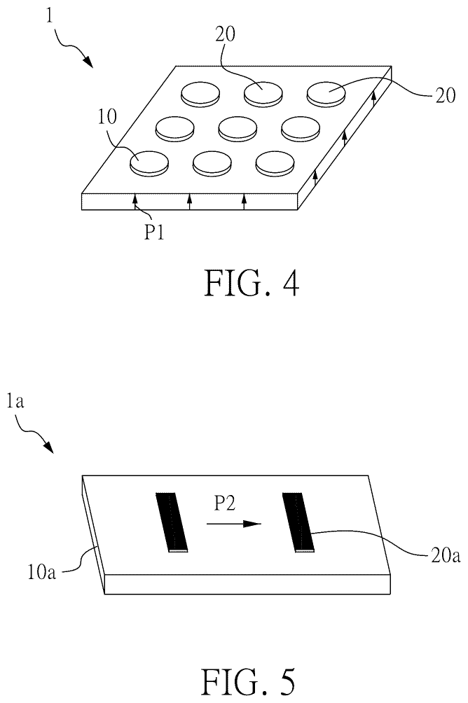

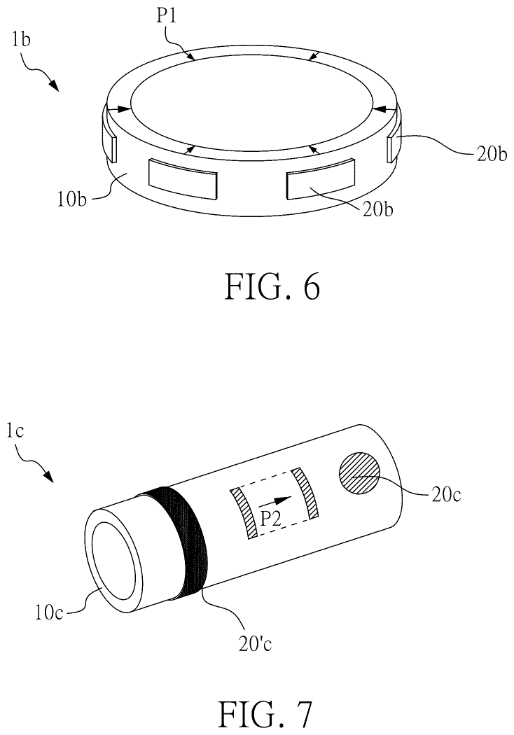

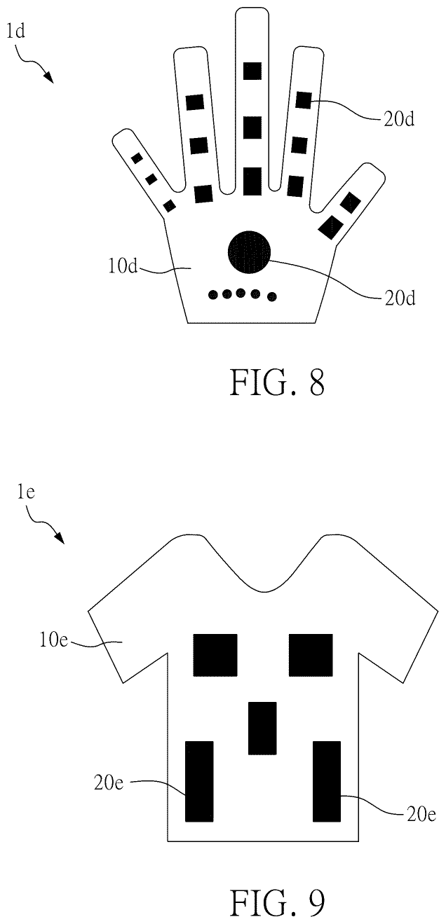

After the mixing procedure is completed, the ceramic kneading machine extrudes the piezoelectric mixed blank to form piezoelectric composite wires. These piezoelectric composite wires are then cut into pellets suitable for feeding into an injection molding machine. The pellets are fed into the injection machine, where they are heated and softened to the softening temperature of the thermoplastic elastomer 12. The material is then extruded by a screw into a mold and held under pressure while being cooled to below the softening point of TPE (around 110° C.) or that of TPU (around 130° C. to 105° C.). After cooling, the piezoelectric composite material 10 of the present disclosure is demolded through injection molding. It is noted that the piezoelectric composite material 10 of the present disclosure can be molded into different thicknesses and sizes depending on the shape of the mold and the specific application requirements. It can be used to create a flat plate (FIG. 4), a tube, a column, a spherical shell, a wire, a ring (FIG. 6), a cylinder (FIG. 7), a glove (FIG. 9), functional clothing (FIG. 8), or various 3D shapes. The thickness range of the piezoelectric composite material 10 of the present disclosure is between 0.3 mm and 4 mm.

Additionally, the piezoelectric composite material 10 of the present disclosure due to its thermoplastic property can be shaped with high precision using a hot press machine mold, followed by micro-shaping. The thickness of the piezoelectric composite material 10 can be reduced to be as low as 0.05 mm. Alternatively, multiple layers of the piezoelectric composite material 10 can be stacked and bonded using heat, or different materials for the inner and outer electrode layers can be thermally bonded. Furthermore, the piezoelectric composite material 10 can be thermoformed from sheet material into various extended components, such as curved surfaces, waves, and rings, thereby enhancing the versatility of the present disclosure.

Step S3: performing thickness poling or surface poling on the piezoelectric composite material to generate at least one polarization zone such that the piezoelectric element is formed.

As shown in FIG. 4 and FIG. 5, after the piezoelectric composite material 10 of the present disclosure is formed, thickness poling and surface poling can be applied to the piezoelectric composite material 10 either entirely or in specific areas, depending on the requirements of the piezoelectric element 1. This process generates at least one polarization zone 20, resulting in the piezoelectric elements 1, la of the present disclosure. Subsequently, when a voltage is applied to the polarization zones 20, 20a, 20a′ of the piezoelectric element 1 of the present disclosure, it can function as an actuator to produce deformation. Alternatively, the piezoelectric element 1 can function as a sensor by generating a voltage signal in response to deformation caused by external forces or torque applied to the polarization zone 20.

It is noted that, as shown in FIG. 4, thickness poling involves applying a high-voltage DC electric field between electrodes to achieve polarization. As shown in FIG. 5, surface poling involves parallel polarization across multiple regions. The piezoelectric composite material 10 of the piezoelectric element 1 of the present disclosure features high strength, high flexibility, and high elasticity, making it suitable for application on curved surfaces or wearable items. Therefore, the piezoelectric element 1 of the present disclosure can be made into wearable items such as clothing, finger cots, gloves, knee pads, etc., to provide piezoelectric sensing for large deformations, bending, and twisting, resulting in high charge signal output. The piezoelectric element 1 of the present disclosure also produces an actuating effect when a voltage is applied.

Please refer to FIG. 1 to FIG. 5, and also refer to FIG. 6 to FIG. 9, which present a schematic diagram of a ring-shaped embodiment, a schematic diagram of a tube-shaped embodiment of the present disclosure, a schematic diagram of an embodiment of the piezoelectric element of the present disclosure used in haptic gloves, and a schematic diagram of an embodiment of the piezoelectric element of the present disclosure used in smart clothing.

As shown in FIG. 1 to FIG. 5, in this embodiment, the piezoelectric element 1 of the present disclosure includes a piezoelectric composite material 10 and at least one polarization zone 20. The piezoelectric element 1 is characterized in that the piezoelectric composite material 10 is composed of a piezoelectric ceramic powder 11 and a thermoplastic elastomer 12 (TPE), wherein the piezoelectric ceramic powder 11 and the thermoplastic elastomer 12 are mixed through a mixing procedure to form a piezoelectric mixed blank. The piezoelectric mixed blank is then shaped into the piezoelectric composite material 10 through injection and thermoplastic procedures. Thickness poling or surface poling is subsequently applied to the piezoelectric composite material 10 to generate at least one polarization zone 20, wherein the volume ratio of the piezoelectric ceramic powder 11 ranges from 40% to 80%.

According to one embodiment of the present disclosure, the mixing procedure involves physically blending the piezoelectric ceramic powder 11 with the thermoplastic elastomer 12 (TPE) in a molten state in a ceramic kneading machine without adding chemical solutions or surface active agents to form a piezoelectric mixed blank. After the mixing procedure is completed, the ceramic kneading machine extrudes the piezoelectric mixed blank to form piezoelectric composite wires. These piezoelectric composite wires are then cut into pellets suitable for feeding into an injection molding machine. The pellets are heated and softened before being fed into the injection machine, where they are extruded into a mold. The material is held under pressure while cooling to below the softening point of TPE (around 110° C.) or that of TPU (around 130° C. to 105° C.) and then demolded to produce the piezoelectric composite material 10 of the present disclosure.

As shown in FIG. 3 and FIG. 4, after the piezoelectric composite material 10 of the present disclosure is formed, thickness poling and surface poling with a DC high-voltage electric field can be applied to the piezoelectric composite material 10, either entirely or in specific areas, depending on the requirements of the piezoelectric element 1. This process generates at least one polarization zone 20 to form the piezoelectric element 1 of the present disclosure. Subsequently, when a voltage is applied to the polarization zone 20, it can function as an actuator to produce deformation. Alternatively, the polarization zone 20 can serve as a sensor by generating a voltage signal in response to deformation caused by external forces or torque.

It is noted that, as shown in FIG. 5 to FIG. 9, the piezoelectric composite material 10 of the present disclosure can be shaped into various forms based on the mold configuration and specific application requirements. This includes the piezoelectric element 1 in a matrix-type shape (FIG. 5), the piezoelectric element 1b in a ring shape (FIG. 6), and the piezoelectric element 1c in a cylindrical tube shape (FIG. 7), in a flat plate shape, in a tube shape, in a columnar shape, in a spherical shell shape, in a wire shape, in a ring shape and in various 3D shapes. Additionally, the piezoelectric element 1 of the present disclosure can be incorporated into wearable items, such as gloves in the piezoelectric element 1d (FIG. 8), finger cots, functional clothing in the piezoelectric element 1e (FIG. 9), or knee pads. These applications enable significant deformation, bending, and twisting for piezoelectric sensing with high charge signal output; when a voltage is applied to the piezoelectric element 1 of the present disclosure, actuating effects are provided.

According to an embodiment, the piezoelectric ceramic powder of the present disclosure can be either a soft piezoelectric ceramic powder (e.g., PZT5A or PZT5H) or a hard piezoelectric ceramic powder (e.g., PZT4 or PZT8). When the particle size of the piezoelectric ceramic powder 11 ranges from 1 μm to 20 μm, 5 μm to 15 μm, or 10 μm to 20 μm, the physical mixing effect with the molten thermoplastic elastomer 12 is satisfactory and the polarization effect is excellent. Furthermore, the piezoelectric output characteristics of the piezoelectric element of the present disclosure are directly proportional to the content of the piezoelectric ceramic powder, while its flexibility (softness) is directly proportional to the content of the thermoplastic elastomer. Experimental results show that a piezoelectric composite material 10 with a volume ratio of the piezoelectric ceramic powder of 45% to 85%, 40% and 80%, or 45% to 75% provides both high piezoelectricity and good flexibility after polarization. Correspondingly, the volume ratio of the thermoplastic elastomer 12 is between 15% and 55%, 20% and 60%, or 25% and 55%.

According to one embodiment of the present disclosure, when the piezoelectric element 1 is used as an actuator, the volume ratio of the piezoelectric ceramic powder 11 in the piezoelectric composite material 10 for this piezoelectric element 1 is between 60% and 80% (i.e., high piezoelectric ceramic content), achieving a combination of high piezoelectricity and flexibility. Conversely, when the piezoelectric element 1 is used as a sensor, the volume ratio of the piezoelectric ceramic powder 11 in the piezoelectric composite material 10 for this piezoelectric element 1 is between 40% and 60% (i.e., lower piezoelectric ceramic content), achieving a balance of piezoelectricity and flexibility. In terms of weight ratio, the ratio of the piezoelectric ceramic powder 11 to the thermoplastic elastomer 12 ranges from 0.3:1 to 3:1.

According to one embodiment of the present disclosure, the thermoplastic elastomer 12 can be a foamed cotton (e.g., foamed cotton used for cushioning in construction sites or buildings). Due to the properties of the foamed cotton, the piezoelectric ceramic powder 11 with a volume ratio greater than 40% can be uniformly physically blended with foamed cotton (thermoplastic elastomer 12) in the molten state during the mixing process. It is noted that, to maintain the elasticity of the thermoplastic elastomer 12, the foamed cotton should not undergo a foaming process (i.e., no compounds or air that would cause the thermoplastic elastomer 12 to foam should be added during mixing), but it can still be evenly mixed. According to another embodiment of the present disclosure, the thermoplastic elastomer 12 is a thermoplastic polyurethane (TPU). In this embodiment, the TPU used is either a polymer elastomer without plasticizers or a TPU foamed cotton commonly used for cushioning in shoe soles to absorb walking impacts. Due to the properties of the foamed cotton, the piezoelectric ceramic powder 11, with a volume ratio greater than 40%, can be uniformly physically blended with the foamed cotton (thermoplastic elastomer 12) during the mixing process. Importantly, no compounds or air that would cause the thermoplastic elastomer 12 to foam are added during this process.

The manufacturing process of the present disclosure involves directly physically mixing the piezoelectric ceramic powder 11 with the thermoplastic elastomer 12 (such as TPE, foamed cotton, TPU, or TPU foamed cotton) in a molten state, without adding chemical solvents. This mixture is then subjected to high-pressure hot injection molding or hot pressing to produce piezoelectric composite materials with high density, high strength, and high flexibility, in various thicknesses, large flat panels, and 3D components. The process of the present disclosure, which omits chemical solutions, not only simplifies the production steps and reduces the cost of manufacturing the piezoelectric element 10 but also minimizes environmental harm caused by chemical solutions.

The above description illustrates and describes several preferred embodiments of the present application. However, it should be understood that the present application is not limited to the forms disclosed herein and should not be construed as excluding other embodiments. It can be applied to various other combinations, modifications, and environments, and can be adapted within the scope of the inventive concepts presented here, based on the teachings provided or the knowledge and techniques in the relevant field. Any modifications and variations made by those skilled in the art that do not depart from the spirit and scope of the present application are intended to be within the scope of the appended claims.

What is claimed is:

1. A piezoelectric element, comprising a piezoelectric composite material and at least one polarization zone, characterized in that the piezoelectric composite material is composed of a piezoelectric ceramic powder and a thermoplastic elastomer (TPE), wherein the piezoelectric ceramic powder and the thermoplastic elastomer form a piezoelectric mixed blank through a mixing procedure, the piezoelectric mixed blank becomes the piezoelectric composite material after injection and thermoplastic procedures, and thickness poling or surface poling is performed on the piezoelectric composite material to generate at least one polarization zone, wherein a volume ratio of the piezoelectric ceramic powder ranges from 40% to 80%, wherein no chemical solutions or surfactants are added during the mixing procedure and the piezoelectric ceramic powder and the thermoplastic polyurethane are only physically blended.

2. The piezoelectric element as claimed in claim 1, wherein the thermoplastic elastomer is a foamed cotton.

3. The piezoelectric element as claimed in claim 2, wherein the thermoplastic elastomer is thermoplastic polyurethane (TPU).

4. The piezoelectric element as claimed in claim 2, wherein the foamed cotton undergoes no foaming procedure.

5. The piezoelectric element as claimed in claim 1, wherein the particle size of the piezoelectric ceramic powder ranges from 1 μm to 20 μm.

6. The piezoelectric element as claimed in claim 1, wherein a weight ratio of the piezoelectric ceramic powder to the thermoplastic elastomer ranges from 0.3:1 to 3:1.

7. The piezoelectric element as claimed in claim 1, wherein the at least one polarization zone is multiple polarization zones.

8. A wearable item comprising the piezoelectric element as claimed in claim 1, wherein the at least one polarization zone is multiple polarization zones.

9. A piezoelectric element manufacture method, for manufacturing a piezoelectric element, the piezoelectric element comprising a piezoelectric composite material and at least one polarization zone, the piezoelectric element manufacturing method comprising the following steps:
mixing the piezoelectric ceramic powder and the thermoplastic elastomer (TPE) in a molten liquefied state to form a piezoelectric mixed blank during a mixing procedure, wherein a volume ratio of the piezoelectric ceramic powder ranges from 40% to 80%, wherein no chemical solutions or surfactants are added during the mixing procedure and the piezoelectric ceramic powder and the thermoplastic polyurethane are only physically blended;
the piezoelectric mixed blank becoming the piezoelectric composite material after injection and thermoplastic procedures; and
performing thickness poling or surface poling on the piezoelectric composite material to generate at least one polarization zone such that the piezoelectric element is formed.

10. The piezoelectric element manufacturing method as claimed in claim 9, wherein the thermoplastic elastomer is a foamed cotton.

11. The piezoelectric element manufacturing method as claimed in claim 10, wherein the foamed cotton undergoes no foaming procedure.

12. The piezoelectric element manufacturing method as claimed in claim 10, wherein the thermoplastic elastomer is thermoplastic polyurethane (TPU).

13. The piezoelectric element manufacturing method as claimed in claim 9, wherein a particle size of the piezoelectric ceramic powder ranges from 1 μm to 20 μm.

14. The piezoelectric element manufacturing method as claimed in claim 9, wherein a weight ratio of the piezoelectric ceramic powder to the thermoplastic elastomer ranges from 0.3:1 to 3:1.

15. The piezoelectric element manufacturing method as claimed in claim 9, wherein the at least one polarization zone is multiple polarization zones.
